(19) United States
(12) Patent Application Publication
(10) Pub. No.: US 2025/0102583 A1
(43) Pub. Date: Mar. 27, 2025

(54) MANUFACTURING METHOD, MANUFACTURING DEVICE, AND NON-TRANSITORY COMPUTER READABLE STORAGE MEDIUM

(71) Applicant: Panasonic Intellectual Property Corporation of America, Torrance, CA (US)

(72) Inventors: Takaaki FUKUNISHI, Osaka (JP); Shinya Nishikawa, Osaka (JP)

(21) Appl. No.: 18/973,800

(22) Filed: Dec. 9, 2024

Related U.S. Application Data
(63) Continuation of application No. PCT/JP2023/018841, filed on May 19, 2023.

(30) Foreign Application Priority Data
Jun. 10, 2022 (JP) 2022-094239

(51) Int. Cl. G01R 31/367; G01R 31/374; G01R 31/3828; G01R 31/3842; G01R 31/392

(52) U.S. Cl. CPC G01R 31/367; G01R 31/374; G01R 31/3828; G01R 31/3842; G01R 31/392

(57) ABSTRACT

A manufacturing device acquires a plurality of pieces of first log data indicating the state of a battery during charge or discharge acquired from a battery-equipped device and a plurality of first degradation levels of the battery, calculates reliability of the respective first degradation levels based on charge or discharge corresponding to the respective pieces of first log data, and outputs a model evaluated to have the best accuracy in estimating the degradation level of the battery out of a model obtained through machine learning of a relationship between the plurality of first degradation levels and the plurality of pieces of first log data, and a model obtained through machine learning of a relationship between first degradation levels having reliability greater than or equal to a predetermined value and first log data corresponding to such first degradation levels.

### FIELD OF INVENTION

The present disclosure relates to a technique for generating a learned model for estimating a degradation level of a chargeable and dischargeable battery.

### BACKGROUND ART

A conventionally known technique is a technique for estimating a degradation level of a battery using a learned model generated by measuring a state of a chargeable and dischargeable battery in a test environment and machine-learning the measured state of the battery. For example, Patent Literature 1 proposes that a prediction model is constructed by learning a relationship between a current, a voltage, and a temperature of a sample battery and a battery capacity for each charge-discharge cycle, and a degradation level of the sample battery is estimated from the battery capacity and a rated capacity predicted by using the prediction model.

However, in Patent Literature 1, since the state of the sample battery has to be measure in each charge-discharge cycle, there is room for improvement in rapidly generating an accurate prediction model.
Patent Literature 1: CN 112051511 A

### SUMMARY OF THE INVENTION

The present disclosure is made to solve the above problem, and an object of the present disclosure is to provide a technique capable of quickly generating a learned model being able to accurately estimate a degradation level of a battery.

A manufacturing method according to one aspect of the present disclosure is a manufacturing method in a manufacturing device of a learned model that estimates a degradation level of a battery being chargeable and dischargeable, the manufacturing method including acquiring a plurality of pieces of first log data acquired from a device equipped with the battery and a plurality of first degradation levels calculated with a degradation level estimation method using each of the plurality of pieces of first log data, the plurality of pieces of first log data indicating a state of the battery during charge or discharge, the plurality of first degradation levels indicating degradation levels of the battery, calculating reliability indicating probability of each of the plurality of first degradation levels respectively corresponding to the plurality of pieces of first log data, based on a content of first charge-discharge that is charge or discharge respectively corresponding to the plurality of pieces of first log data, generating a first learned model by machine-learning a relationship between the plurality of first degradation levels and the plurality of pieces of first log data, generating a second learned model by machine-learning a relationship between first degradation levels having the reliability greater than or equal to a predetermined value among the plurality of first degradation levels and first log data corresponding to the first degradation levels having the reliability greater than or equal to the predetermined value among the plurality of pieces of first log data, evaluating accuracy in estimating the degradation levels of the battery in each of the first learned model and the second learned model, and outputting a learned model evaluated to have the estimation accuracy being best in the first learned model and the second learned model.

### BRIEF DESCRIPTION OF THE DRAWINGS

FIG. 1 is a diagram illustrating an overall configuration of a model manufacturing system according to a first embodiment of the present disclosure.

FIG. 2 is a diagram illustrating one example of a relationship between coefficients and contents of charge-discharge.

FIG. 3 is a diagram illustrating one example of a feature amount used as an explanatory variable of machine learning.

FIG. 4 is a flowchart illustrating one example of a model manufacturing process.

FIG. 5 is a diagram illustrating one example of a process for extracting first degradation levels within a predetermined variation range.

### DETAILED DESCRIPTION

### (Knowledge Underlying Present Disclosure)

In the above-described conventional technique, annual time cost and operation cost of a test environment are required in order to acquire data used for machine learning in the test environment. Therefore, in recent years, a degradation level estimation method has been proposed with which log data indicating a state of a battery at during actual charge or discharge is acquired from a device, such as an electric vehicle, equipped with the battery, and a degradation level of the battery is calculated using the log data. However, with the degradation level estimation method, data used for calculating the degradation level of the battery can be quickly acquired, but the accuracy in calculating the degradation level of the battery is low.

For example, with a point-to-point open circuit voltage (OCV) estimation method known as the degradation level estimation method, data indicating a voltage of a battery in a battery suspended state immediately before and after charge-discharge is acquired as data indicating an open circuit voltage of the battery, and the degradation level of the battery is calculated using the open circuit voltage. However, due to a short period of the battery suspended state or the like, data indicating the voltage of the battery at a time of a chemical reaction not being completed inside the battery may be acquired as data indicating the open circuit voltage of the battery. In this case, the degradation levels of the battery may not be accurately calculated using the open circuit voltage.

Therefore, the present inventor has intensively studied a technique capable of quickly generating a learned model capable of accurately estimating the degradation level of the battery, and has arrived at each aspect of the present disclosure described below.

(1) A manufacturing method according to one aspect of the present disclosure is a manufacturing method in a manufacturing device of a learned model that estimates a degradation level of a battery being chargeable and dischargeable, the manufacturing method including acquiring a plurality of pieces of first log data acquired from a device equipped with the battery and a plurality of first degradation levels calculated with a degradation level estimation method using each of the plurality of pieces of first log data, the plurality of pieces of first log data indicating a state of the battery during charge or discharge, the plurality of first degradation levels indicating degradation levels of the battery, calculating reliability indicating probability of each of the plurality of first degradation levels respectively corresponding to the plurality of pieces of first log data, based on a content of first charge-discharge that is charge or discharge respectively corresponding to the plurality of pieces of first log data, generating a first learned model by machine-learning a relationship between the plurality of first degradation levels and the plurality of pieces of first log data, generating a second learned model by machine-learning a relationship between first degradation levels having the reliability greater than or equal to a predetermined value among the plurality of first degradation levels and first log data corresponding to the first degradation levels having the reliability greater than or equal to the predetermined value among the plurality of pieces of first log data, evaluating accuracy in estimating the degradation levels of the battery in each of the first learned model and the second learned model, and outputting a learned model evaluated to have the estimation accuracy being best in the first learned model and the second learned model.

In this configuration, the plurality of pieces of first log data indicating the state of the battery during charge or discharge is acquired from the device equipped with the battery. Therefore, this configuration enables the plurality of pieces of first log data necessary for machine learning for generating the first learned model and the second learned model to be acquire more quickly than a case where the first log data is acquired by conducting a plurality of charge-discharge tests in a test environment. As a result, this configuration enables the first learned model and the second learned model to be quickly generate.

Further, in this configuration, the second learned model is generated by machine-learning the relationship between the first degradation levels having reliability greater than or equal to a predetermined value and the first log data corresponding to such first degradation levels. Therefore, this configuration makes it possible to generate the second learned model that is considered to estimate the degradation levels of the battery with higher accuracy than the first learned model that is likely to have machine-learned the relationship between first degradation levels having reliability less than the predetermined value and the first log data corresponding to such first degradation levels.

However, even the second learned model generated in this manner does not always have the accuracy in estimating the degradation levels of the battery higher than that of the first learned model. Therefore, in this configuration, the accuracy in estimating the degradation levels of the battery in each of the first learned model and the second learned model is evaluated, and the learned model evaluated to have the best estimation accuracy is output. Thus, this configuration makes it possible to output the learned model capable of accurately estimating the degradation levels of the battery.

(2) The manufacturing method described in (1), further includes extracting first degradation levels within a predetermined variation range among the plurality of first degradation levels, and generating a third learned model by machine-learning a relationship between the extracted first degradation levels and first log data corresponding to the extracted first degradation levels, wherein the evaluating includes further evaluating the estimation accuracy in the third learned model, and wherein the outputting includes outputting a learned model evaluated to have the estimation accuracy being best among the first learned model, the second learned model, and the third learned model.

In the present configuration, the third learned model is generated by machine-learning the relationship between the first degradation levels within the predetermined variation range and the first log data corresponding to such first degradation levels. Therefore, this configuration makes it possible to generate the third learned model that is considered to estimate the degradation levels of the battery with higher accuracy than the first learned model that is likely to have machine-learned the relationship between first degradation levels outside the variation range and the first log data corresponding to such first degradation levels.

However, even the third learned model generated in this manner does not always have the accuracy in estimating the degradation levels of the battery, the accuracy being higher than that of the first learned model and the second learned model. Therefore, in this configuration, the accuracy in estimating the degradation levels of the battery in the third learned model is further evaluated, and a learned model evaluated to have the best estimation accuracy among the first learned model, the second learned model, and the third learned model is output. Thus, this configuration makes it possible to output the learned model capable of accurately estimating the degradation levels of the battery.

(3) The manufacturing method described in (2), further includes generating a fourth learned model by machine-learning a relationship between first degradation levels having the reliability greater than or equal to the predetermined value among the extracted first degradation levels and first log data corresponding to the first degradation levels having the reliability greater than or equal to the predetermined value among the extracted first degradation levels, wherein the evaluating further includes evaluating the estimation accuracy in the fourth learned model, and wherein the outputting includes outputting a learned model evaluated to have the estimation accuracy being best among the first learned model, the second learned model, the third learned model, and the fourth learned model.

In this configuration, the fourth learned model is generated by machine-learning the relationship between the first degradation levels having the reliability greater than or equal to the predetermined value among the first degradation levels within the predetermined variation range and first log data corresponding to such first degradation levels. Therefore, this configuration makes it possible to generate the fourth learned model that is considered to estimate the degradation levels of the battery with higher accuracy than the third learned model that is likely to have machine-learned the relationship between first degradation levels having the reliability less than the predetermined value among the first degradation levels within the variation range and the first log data corresponding to such first degradation levels.

However, even the fourth learned model generated in this manner does not always have the accuracy in estimating the degradation levels of the battery, the accuracy being higher than that of the first learned model, the second learned model, and the third learned model. Therefore, in this configuration, the accuracy in estimating the degradation levels of the battery in the fourth learned model is further evaluated, and the learned model evaluated to have the best estimation accuracy among the first learned model, the second learned model, the third learned model, and the fourth learned model is output. Thus, this configuration makes it possible to output the learned model capable of accurately estimating the degradation levels of the battery.

(4) In the manufacturing method described in any one of (1) to (3), wherein the evaluating may include acquiring second log data acquired from the device equipped with the battery and second degradation levels calculated with the degradation level estimation method using the second log data, the second log data indicating a state of the battery during second charge for charging the battery until an SOC of the battery changes from 0% to 100% in a case where a temperature of the battery is between 20 degrees and 30 degrees, the second degradation levels indicating degradation levels of the battery, calculating a deviation level between the second degradation levels and degradation levels of the battery estimated by inputting the second log data to each of the plurality of learned models to be evaluated, and evaluating a learned model having the deviation level being lowest among the plurality of learned models as the learned model having the best estimation accuracy.

This configuration makes it possible to appropriately and quickly evaluate the accuracy in estimating the degradation levels of the battery in each of the plurality of learned models using the second log data indicating the state of the battery during the second charge, the second log data being acquired from the device equipped with the battery.

(5) In the manufacturing method described in (1), the calculating the reliability includes calculating, as the reliability, a result of multiplying an initial value of the reliability greater than the predetermined value by a coefficient corresponding to the content of the first charge-discharge.

This configuration makes it possible to appropriately calculate the reliability of the first degradation level corresponding to each piece of the first log data using the coefficient corresponding to the content of the first charge-discharge.

(6) In the manufacturing method described in (5), the coefficient may be determined as a difference between an SOC of the battery at start of the first charge-discharge and an SOC of the battery at end of the first charge-discharge.

In this configuration, the smaller the difference between the SOC of the battery at the start of the first charge-discharge and the SOC of the battery at the end of the first charge-discharge, the lower the reliability is calculated. Therefore, in this configuration, as the difference between the SOC of the battery at the start of the first charge-discharge and the SOC of the battery at the end is smaller, the possibility that the first log data corresponding to the first charge-discharge is machine-learned to generate the second learned model can be made lower.

(7) In the manufacturing method described in (5) or (6), the calculating the reliability includes performing multiplication by a coefficient smaller than 1 in a case where a time during which the battery is in a suspended state immediately before the first charge-discharge is shorter than a predetermined time.

In this configuration, in the case where the time during which the battery is in the suspended state immediately before the first charge-discharge is shorter than the predetermined time, the reliability lower than the initial value is calculated. Therefore, this configuration makes it possible to reduce the possibility that the first log data corresponding to the first charge-discharge immediately after the time during which the battery is in the suspended state is shorter than the predetermined time is machine-learned to generate the second learned model.

(8) In the manufacturing method described in any one of (5) to (7), the calculating the reliability includes performing multiplication by a coefficient smaller than 1 in a case where each of the plurality of first degradation levels respectively corresponding to the plurality of pieces of first log data is greater than a predetermined upper limit value or smaller than a predetermined lower limit value.

In this configuration, in the case where each of the plurality of first degradation levels respectively corresponding to the plurality of pieces of first log data is greater than a predetermined upper limit value or smaller than a predetermined lower limit value, the reliability smaller than an initial value is calculated. Therefore, this configuration makes it possible to reduce the possibility that the first degradation levels and the first log data are machine-learned to generate the second learned model in a case where the first degradation levels greater than the upper limit value or smaller than the lower limit value are calculated using the first log data.

(9) In the manufacturing method describe in (1), the degradation level estimation method includes acquiring a voltage of the battery in a battery suspended state each of immediately before and after the first charge-discharge as an open circuit voltage of the battery each of immediately before and after the first charge-discharge, designating the open circuit voltage of the battery each of immediately before and after the first charge-discharge as an SOC of the battery at each of start and end of the first charge-discharge, with reference to information indicating a relationship between the SOC of the battery and the open circuit voltage of the battery, calculating a difference in the SOC of the battery at each of the start and the end of the first charge-discharge, calculating an integrated value of currents of the battery during the first charge-discharge using each of the plurality of pieces of first log data, and calculating, as the degradation level of the battery, a result of dividing a result of dividing the integrated value by the difference by a full charge capacity of the battery in an initial state.

This configuration makes it possible to quickly calculate the first degradation levels by using each of the plurality of pieces of first log data acquired from the device equipped with the battery and the full charge capacity of the battery in the initial state.

(10) In the manufacturing method describe in (4), the degradation level estimation method includes acquiring a voltage of the battery in a battery suspended state each of immediately before and after the second charge as an open circuit voltage of the battery each of immediately before and after the second charge, designating the open circuit voltage of the battery each of immediately before and after the second charge as the SOC of the battery at each of the start and the end of the second charge, with reference to information indicating a relationship between the SOC of the battery and the open circuit voltage of the battery, calculating a difference in the SOC of the battery at each of the start and the end of the second charge, calculating an integrated value of currents of the battery during the second charge using the second log data, and calculating a result of dividing a result of dividing the integrated value by the difference by a full charge capacity of the battery in an initial state, as the degradation level of the battery.

This configuration makes it possible to quickly calculate the second degradation levels by using each piece of the second log data acquired from the device equipped with the battery and the full charge capacity of the battery in the initial state.

(11) In the manufacturing method described in (2) or (3), the extracting the first degradation levels within the variation range includes performing linear regression in which a square root of an elapsed time from an initial state of the battery to end of the first charge-discharge is an explanatory variable and each of the first degradation levels is an objective variable, and extracting first degradation levels at which a distance up to a regression line obtained by the linear regression is a predetermined distance or shorter among the plurality of first degradation levels, as the first degradation levels within the variation range.

This configuration makes it possible to appropriately extract the first degradation levels within the predetermined variation range among the plurality of first degradation levels using the regression line obtained by performing the linear regression.

(12) A manufacturing device according to another aspect of the present invention is a manufacturing device of a learned model that estimates a degradation level of a battery being chargeable or dischargeable, the manufacturing device including an acquisition unit that acquires a plurality of pieces of first log data acquired from a device equipped with the battery and a plurality of first degradation levels calculated with a degradation level estimation method using each of the plurality of pieces of first log data, the plurality of pieces of first log data indicating a state of the battery during charge or discharge, the plurality of first degradation levels indicating degradation levels of the battery, a calculation unit that calculates reliability indicating probability of each of the plurality of first degradation levels respectively corresponding to the plurality of pieces of first log data, based on a content of first charge-discharge that is charge or discharge respectively corresponding to each of the plurality of pieces of first log data, a first generation unit that generates a first learned model by machine-learning a relationship between the plurality of first degradation levels and the plurality of pieces of first log data, a second generation unit that generates a second learned model by machine-learning a relationship between first degradation levels having the reliability greater than or equal to a predetermined value among the plurality of first degradation levels and first log data corresponding to the first degradation levels having the reliability greater than or equal to the predetermined value among the plurality of pieces of first log data, an evaluation unit that evaluates accuracy in estimating the degradation levels of the battery in each of the first learned model and the second learned model, and an output unit that outputs a learned model evaluated to have the estimation accuracy being best in the first learned model and the second learned model.

According to this configuration, the same operation and effect as those of the manufacturing method described in (1) can be obtained.

(13) A non-transitory computer readable storage medium according to another aspect of the present disclosure is a non-transitory computer readable storage medium storing a program of a manufacturing device of a learned model that estimates a degradation level of a battery being chargeable and dischargeable, the program causing the manufacturing device to perform operations comprising: acquiring a plurality of pieces of first log data acquired from a device equipped with the battery and a plurality of first degradation levels calculated with a degradation level estimation method using each of the plurality of pieces of first log data, the plurality of pieces of first log data indicating a state of the battery during charge or discharge, the plurality of first degradation levels indicating degradation levels of the battery; calculating reliability indicating probability of each of the plurality of first degradation levels respectively corresponding to the plurality of pieces of first log data, based on contents of first charge-discharge that is charge or discharge respectively corresponding to the plurality of pieces of first log data; generating a first learned model by machine-learning a relationship between the plurality of first degradation levels and the plurality of pieces of first log data; generating a second learned model by machine-learning a relationship between first degradation levels having the reliability greater than or equal to a predetermined value among the plurality of first degradation levels and first log data corresponding to the first degradation levels having the reliability greater than or equal to the predetermined value among the plurality of pieces of first log data; evaluating estimation accuracy of the plurality of degradation levels of the battery in each of the first learned model and the second learned model; and outputting a learned model evaluated to have the estimation accuracy being best in the first learned model and the second learned model.

According to this configuration, the same operation and effect as those of the manufacturing method described in (1) can be obtained.

The present disclosure can also be implemented as a system that operates by a program as described above. It is needless to say that such a computer program can be distributed via a computer-readable non-transitory recording medium such as a CD-ROM, or via a communication network such as the Internet.

Note that all embodiments described below illustrates specific examples of the present disclosure. Numerical values, shapes, components, steps, order of steps, and the like described in the following embodiments are merely examples and are not intended to limit the present disclosure. Components that are not described in independent claims representing the highest concept among components in the embodiments below are described as arbitrary components. In all the embodiments, respective contents can be combined.

### First Embodiment

A first embodiment of the present disclosure will be described below with reference to the drawings. In the following first embodiment, the same portions are denoted by the same reference signs, and are omitted from the description.

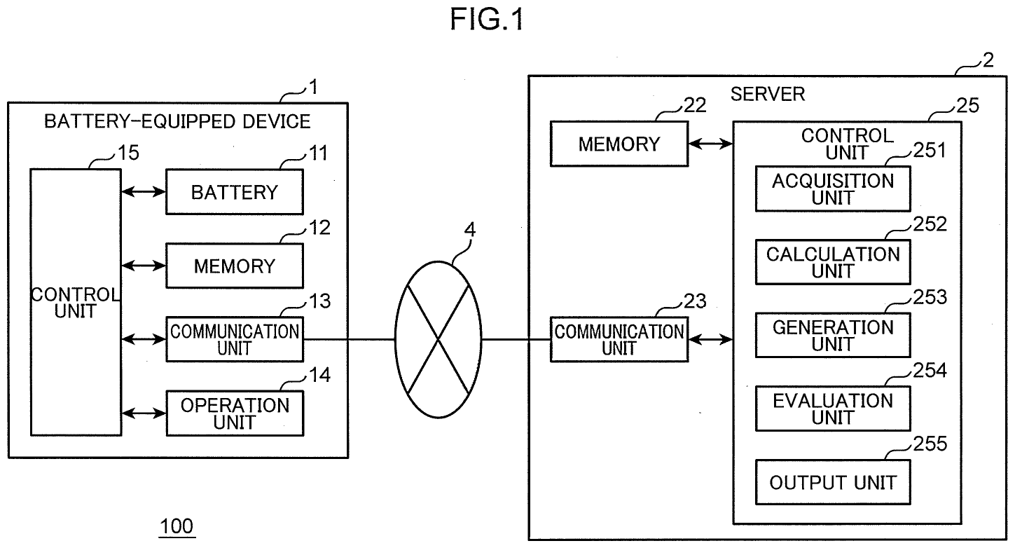

FIG. 1 is a diagram illustrating an overall configuration of a model manufacturing system 100 according to the first embodiment of the present disclosure. The model manufacturing system 100 includes a battery-equipped device 1 and a server 2 (manufacturing device). The battery-equipped device 1 and the server 2 are communicably connected to each other via a network 4. The network 4 is the Internet, for example.

The battery-equipped device 1 is, for example, an electric vehicle, such as an electric car, an electric truck, an electric motorcycle, or an electric bicycle, which is equipped with a chargeable-dischargeable battery 11 and is moved by electric power charged in the battery 11. The battery-equipped device 1 is not limited to this, and may be an electric mobile object, such as a drone, a ship, or a robot, which is equipped with the chargeable-dischargeable battery 11 and which is moved by the electric power charged in the battery 11. Further, the battery-equipped device 1 may be a stationary power supply device that is equipped with the battery 11 that stores power supplied from a solar power generator, a power supply company, or the like and supplies the power charged in the battery 11 to a facility.

The battery-equipped device 1 periodically transmits log data indicating the state of the battery 11 to the server 2. Details of the log data will be described later.

The server 2 is, for example, a cloud server. The server 2 receives various kinds of information such as log data from the battery-equipped device 1. The server 2 generates a plurality of degradation level estimation models (learned models) for estimating the degradation level of the battery 11, based on the log data acquired from the battery-equipped device 1. The degradation level of the battery 11 indicates how much the battery 11 is degraded with respect to an initial state. The server 2 outputs a degradation level estimation model having best accuracy in estimating the degradation level among the plurality of degradation levels estimation models.

Hereinafter, configurations of the battery-equipped device 1 and the server 2 will be described. The battery-equipped device 1 includes the battery 11, a memory 12, a communication unit 13, an operation unit 14, and a control unit 15.

The battery 11 is, for example, a chargeable-dischargeable secondary battery such as a lithium ion battery. The battery 11 discharges (supplies) the power stored therein to various operation units included in the battery-equipped device 1. Note that in a case where the battery-equipped device 1 is a stationary power supply device, the battery 11 discharges (supplies) the power stored in the battery to an external device via a power cable not illustrated.

The memory 12 is, for example, a storage device, such as a random access memory (RAM), a solid state drive (SSD), or a flash memory, capable of storing various types of information.

The communication unit 13 is a communication interface circuit that transmits and receives various types of information to and from an external device such as the server 2 via the network 4.

The operation unit 14 receives an operation of the battery-equipped device 1. The operation unit 14 includes a liquid crystal display, a touch panel device, and the like.

The control unit 15 is a microcomputer including a processor, a non-volatile memory, such as a random access memory (RAM) or a read only memory (ROM), an input-output circuit, a timer circuit, and various measurement circuits, and the like. The various measurement circuits include a measurement circuit that measures a current, a voltage, and a temperature of the battery 11.

The control unit 15 charges the battery 11 with power supplied via a power cable not illustrated.

The control unit 15 measures the state of the battery 11 periodically, for example, every 10 seconds, and stores log data indicating the measurement results in the memory 12. The log data includes, for example, time when the state of the battery 11 is measured (hereinafter, measurement time) and information indicating the measurement result of the state of the battery 11 (hereinafter, state information). The state of the battery 11 includes the current, voltage, and temperature of the battery 11.

The control unit 15 periodically transmits the log data stored in the memory 12 to the server 2 using the communication unit 13. The timing at which the control unit 15 transmits the log data to the server 2 is not limited thereto. For example, the control unit 15 may transmit the log data stored in the memory 12 to the server 2 using the communication unit 13 at a timing when charge-discharge of the battery 11 ends. Further, the control unit 15 may transmit the log data stored in the memory 12 to the server 2 using the communication unit 13 at a timing when the charge-discharge a predetermined number of times ends.

When the communication unit 13 receives the degradation level estimation model that estimates the degradation level of the battery 11 from the server 2, the control unit 15 stores the degradation level estimation model in the memory 12. In addition, the control unit 15 requests the server 2 to transmit the degradation level estimation model using the communication unit 13 at the timing when the charge-discharge of the battery 11 ends. The control unit 15 stores, in the memory 12, the degradation level estimation model received by the communication unit 13 from the server 2 in response to the request. The timing at which the control unit 15 requests the server 2 to transmit the degradation level estimation model is not limited thereto. For example, the control unit 15 may request the server 2 to transmit the degradation level estimation model in response to the operation from the user through the operation unit 14.

When log data indicating the state of the battery 11 during charge-discharge is input, the degradation level estimation model outputs the degradation level of the battery 11 during the charge-discharge. The during charge-discharge is a period from start to end of charge or discharge of the battery 11.

The control unit 15 estimates the degradation level of the battery 11 at the timing when the charge-discharge of the battery 11 ends. The timing at which the control unit 15 estimates the degradation level of the battery 11 is not limited thereto. For example, the control unit 15 may estimate the degradation level of the battery 11 in response to the operation from the user through the operation unit 14.

Specifically, the control unit 15 acquires the degradation level estimation model stored in the memory 12, and inputs the log data stored in the memory 12 during the latest charge-discharge to the degradation level estimation model. As a result, when the degradation level estimation model outputs the degradation level of the battery 11, the control unit 15 displays the degradation level on the liquid crystal display included in the operation unit 14.

The server 2 includes a memory 22, a communication unit 23, and a control unit 25.

The communication unit 23 is a communication interface circuit that transmits and receives various types of information to and from an external device such as the battery-equipped device 1 via the network 4. For example, when receiving the log data from the battery-equipped device 1, the communication unit 23 outputs the received log data to the control unit 25. Further, the communication unit 23 transmits the degradation level estimation model having the best accuracy in estimating the degradation level to the battery-equipped device 1 under the control by the control unit 25.

The memory 22 is a storage device, such as a random access memory (RAM), a hard disk drive (HDD), a solid state drive (SSD), or a flash memory, capable of storing various types of information. The memory 22 stores a control program executed by the control unit 25.

The memory 22 stores the log data received by the communication unit 23 from the battery-equipped device 1. The memory 22 stores information about the battery 11 (hereinafter, battery information). The battery information includes a characteristic table indicating a relationship between a state of charge (SOC) of the battery 11 and the voltage of the battery 11, a full charge capacity of the battery 11 in the initial state, and the like. The SOC is an index representing a charging rate of the battery 11. The SOC is represented by (remaining capacity [Ah]/full charge capacity [Ah]).

The control unit 25 is, for example, a central processing unit (CPU). The control unit 25 functions as an acquisition unit 251, a calculation unit 252, a generation unit 253 (a first generation unit and a second generation unit), an evaluation unit 254, and an output unit 255 by executing the control program stored in the memory 22.

The acquisition unit 251 acquires the log data received by the communication unit 23 from the battery-equipped device 1, and stores the log data in the memory 22.

Further, the acquisition unit 251 acquires a plurality of pieces of log data (hereinafter, first log data) indicating the state of the battery 11 during charge or discharge from the memory 22 in a model manufacturing process described later.

Specifically, the acquisition unit 251 determines whether the battery 11 is being charged or discharged when the log data is acquired, with reference to a current value of the battery 11 included in the log data. The acquisition unit 251 acquires a plurality of pieces of the first log data indicating the state of the battery 11 during charge or discharge by making the determination.

For example, it is assumed that the current value of the battery 11 included in the log data falls within a predetermined range close to 0. In this case, when the log data is acquired, the acquisition unit 251 determines that the battery 11 is not being charged or discharged and the battery 11 is in a suspended state.

It is assumed that the current value of the battery 11 included in the log data is a current value (for example, a negative value) outside the predetermined range during the discharge. In this case, the acquisition unit 251 determines that the battery 11 is being discharged when the log data is acquired. It is assumed that the current value of the battery 11 included in the log data is a current value (for example, a positive value) outside the predetermined range during the charge. In this case, the acquisition unit 251 determines that the battery 11 is being charged when the log data is acquired.

The acquisition unit 251 calculates a degradation level (hereinafter, a first degradation level) of the battery 11 during charge-discharge (hereinafter, first charge-discharge) corresponding to each piece of acquired first log data with a degradation level estimation method. The first charge-discharge indicates the charge or discharge of the battery 11 performed when the first log data is acquired in the battery-equipped device 1.

In the present embodiment, the degradation level of the battery 11 is represented by a state of health (SOH) of the battery 11. The SOH is represented by (full charge capacity [Ah] during degradation (current)/full charge capacity [Ah] at a time when battery 11 is in the initial state). Further, the acquisition unit 251 calculates the first degradation level with a point-to-point open circuit voltage (OCV) estimation method known as the degradation level estimation method using the first log data.

Specifically, the acquisition unit 251 acquires the voltages of the battery 11 in the suspended state immediately before and after the first charge-discharge, as open circuit voltages of the battery 11 immediately before and after the first charge-discharge, with reference to the log data stored in the memory 22. Immediately before the charge-discharge means immediately before charge or discharge of the battery 11 starts. Immediately after charge-discharge indicates immediately after charge or discharge of the battery 11 ends.

The acquisition unit 251 designates open circuit voltages of the battery 11 immediately before and after the first charge-discharge as the SOC of the battery 11 at the start and end of the first charge-discharge, with reference to the characteristic table stored in the memory 22. The acquisition unit 251 calculates a difference (hereinafter, an SOC difference) between the SOC of the battery 11 at the start of the first charge-discharge and the SOC of the battery 11 at the end of the first charge-discharge.

The acquisition unit 251 calculates an integrated value of the currents of the battery 11 during the first charge-discharge with reference to the current value of the battery 11 included in the first log data. The acquisition unit 251 divides a result (=integrated value of currents/SOC difference), which is obtained by dividing the calculated integrated value by the SOC difference, by the full charge capacity of the battery 11 in the initial state stored in the memory 22. The calculation unit 252 calculates the result of the division (=integrated value of currents/(SOC difference×full charge capacity of the battery 11 in the initial state)) as the first degradation level.

The calculation unit 252 calculates reliability indicating probability of the first degradation level corresponding to each piece of the first log data, based on the content of the first charge-discharge corresponding to each piece of the first log data acquired by the acquisition unit 251. The first degradation level corresponding to the first log data indicates the first degradation level during the first charge-discharge corresponding to the first log data, the first degradation level being calculated using the first log data.

Specifically, the calculation unit 252 calculates a result of multiplying the initial value of the reliability by a coefficient corresponding to the content of the first charge-discharge, as the reliability.

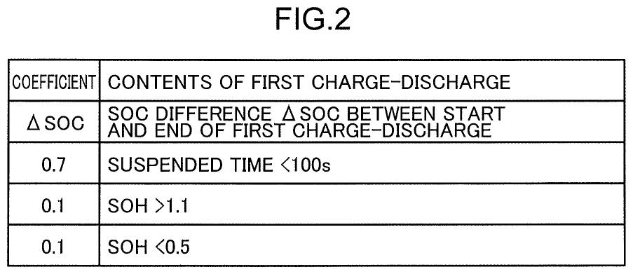

FIG. 2 is a diagram showing one example of a relationship between the coefficient and the content of charge-discharge. For example, FIG. 2 shows that the coefficient includes a coefficient “ASOC” determined as an SOC difference that is the difference between the SOC of the battery 11 at the start of the first charge-discharge and the SOC of the battery 11 at the end of the first charge-discharge. That is, after setting the reliability to a predetermined initial value (for example, 1), the calculation unit 252 calculates a result (for example, 0.9) of multiplying the reliability by the SOC difference (for example, 0.9) calculated at the time of calculating the first degradation level, as the reliability.

FIG. 2 further shows that the coefficient “0.7” (coefficient smaller than 1) is determined in association with a case where the time during which the battery 11 is in the suspended state immediately before the first charge-discharge (hereinafter, suspended time) is shorter than 100 seconds (“suspended time <100 ms”). That is, in a case where the suspended time immediately before the first charge-discharge is shorter than 100 seconds (predetermined time), the calculation unit 252 calculates a result (for example, 0.63) of further multiplying the reliability (for example, 0.9) calculated so far by the coefficient “0.7”, as the reliability.

FIG. 2 further shows that the coefficient “0.1” is determined in association with a case where the first degradation level corresponding to each first log data is greater than 1.1 (predetermined upper limit value) (“SOH>1.1”). That is, when the first degradation level corresponding to each first log data is greater than 1.1, the calculation unit 252 calculates a result (for example, 0.063) of further multiplying the reliability (for example, 0.63) calculated so far by the coefficient “0.1”, as the reliability.

FIG. 2 further shows that the coefficient “0.1” is determined in association with a case where the first degradation level corresponding to each first log data is smaller than 0.5 (predetermined lower limit value) (“SOH<0.5”). That is, when the first degradation level corresponding to each first log data is smaller than 0.5, the calculation unit 252 calculates a result (for example, 0.063) of further multiplying the reliability (for example, 0.63) calculated so far by the coefficient “0.1”, as the reliability.

The generation unit 253 generates a first degradation level estimation model (first learned model) by machine-learning the relationship between the plurality of first degradation levels calculated by the acquisition unit 251 and the plurality of pieces of first log data acquired by the acquisition unit 251.

In addition, the generation unit 253 generates a second degradation level estimation model (second learned model) by machine-learning a relationship between first degradation levels having the reliability greater than or equal to a predetermined value among the plurality of first degradation levels calculated by the acquisition unit 251 and first log data corresponding to such first degradation levels. The first log data corresponding to the first degradation levels means first log data used for calculating the first degradation levels. The predetermined value is set to a value (for example, 0.8) smaller than an initial value (for example, 1) of the reliability. In other words, the initial value of the reliability is set to a value greater than the predetermined value.

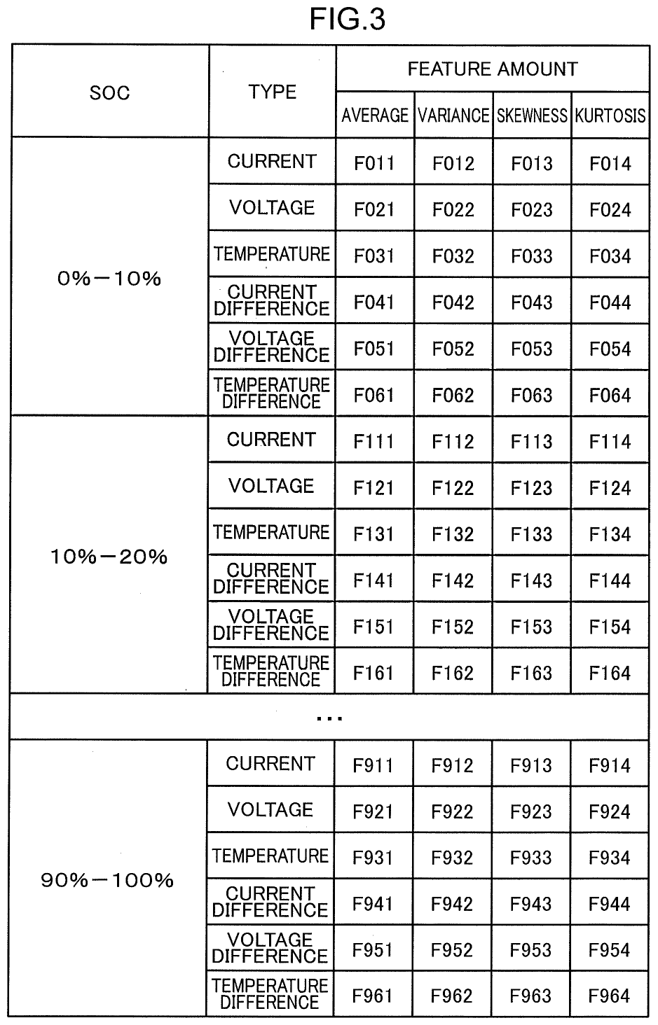

FIG. 3 is a diagram illustrating one example of a feature amount used as an explanatory variable of machine learning. Specifically, when generating the first degradation level estimation model, the generation unit 253 calculates the feature amount illustrated in FIG. 3 with reference to the voltage, the current, and the temperature of the battery 11 included in the first log data corresponding to the first degradation level.

More specifically, the generation unit 253 classifies the period during which the first charge-discharge is performed into ten periods in accordance with the SOC of the battery 11.

For example, the generation unit 253 calculates the SOC of the battery 11 using the SOC of the battery 11 at the start of the first charge-discharge, the integrated value of the currents of the battery 11 included in the first log data from the start of the first charge-discharge, and the full charge capacity of the battery 11 in the initial state. The SOC of the battery 11 at the start of the first charge-discharge may be calculated by the acquisition unit 251 calculating the first degradation level.

The generation unit 253 calculates an average value, a variance value, skewness, and kurtosis of the current, the voltage, the temperature, the current difference, the voltage difference, and the temperature difference of the battery 11 in each classified period, as the feature amounts.

The current difference indicates a change amount of the current of the battery 11. The generation unit 253 acquires the current value of the battery 11 from the first log data including the most recent measurement time before the measurement time included in the first log data. The generation unit 253 calculates the current difference by subtracting the acquired current value from the current value of the battery 11 included in the first log data.

The voltage difference indicates a change amount of the voltage of the battery 11. The generation unit 253 acquires the voltage value of the battery 11 from the first log data including the most recent measurement time before the measurement time included in the first log data. The generation unit 253 calculates the voltage difference by subtracting the acquired voltage value from the voltage value of the battery 11 included in the first log data.

The temperature difference indicates a change amount of the temperature of the battery 11. The generation unit 253 acquires the temperature value of the battery 11 from the first log data including the most recent measurement time before the measurement time included in the first log data. The generation unit 253 calculates the temperature difference by subtracting the acquired temperature value from the temperature value of the battery 11 included in the first log data.

For example, it is assumed that the first log data corresponding to the first degradation levels is log data acquired when charge is performed until the SOC of the battery 11 changes from 0% to 20%. In this case, the generation unit 253 calculates, as the feature amounts, an average value “F011”, a variance value “F012”, skewness “F013”, and kurtosis “F014” of the current of the battery 11 in a period until the SOC of the battery 11 changes from 0% to 10%.

Similarly, the generation unit 253 calculates, as feature amounts, an average value “F021”, a variance value “F022”, skewness “F023”, and kurtosis “F024” of the voltage of the battery 11 in the period until the SOC of the battery 11 changes from 0% to 10%, an average value “F031”, a variance value “F032”, skewness “F033”, and kurtosis “F034” of the temperature, an average value “F041”, a variance value “F042”, skewness “F043”, and kurtosis “F044” of the current difference, an average value “F051”, a variance value “F052”, skewness “F053”, and kurtosis “F054” of the voltage difference, an average value “F061”, a variance value “F062”, skewness “F063”, and kurtosis “F064” of the temperature difference.

Similarly, the generation unit 253 calculates, as feature amounts, an average value “F111”, a variance value “F112”, skewness “F113”, and kurtosis “F114” of the current of the battery 11 in the period until the SOC of the battery 11 changes from 10% to 20%, an average value “F121”, a variance value “F122”, skewness “F123”, and kurtosis “F124” of the voltage, an average value “F131”, a variance value “F132”, skewness “F133”, and kurtosis “F134” of the temperature, an average value “F141”, a variance value “F142”, skewness “F143”, and kurtosis “F144” of the current difference, an average value “F151”, a variance value “F152”, skewness “F153”, and kurtosis “F154” of the voltage difference, an average value “F161”, a variance value “F162”, skewness “F163”, and kurtosis “F164” of the temperature difference.

The generation unit 253 performs machine learning with a predetermined learning algorithm using the feature amounts calculated with reference to the first log data as explanatory variables and the first degradation levels corresponding to the first log data as objective variables. As a result, the generation unit 253 generates the first degradation level estimation model that outputs the degradation levels of the battery 11 during the charge-discharge corresponding to the first log data in a case where the first log data is input.

Similarly, the generation unit 253 calculates the feature amounts with reference to the first log data corresponding to the first degradation levels having the reliability greater than or equal to the predetermined value. The generation unit 253 performs machine learning with a predetermined learning algorithm using the feature amounts as explanatory variables and the first degradation levels as objective variables. As a result, the generation unit 253 generates the second degradation level estimation model that outputs the degradation levels of the battery 11 during charge-discharge corresponding to the first log data in a case where the first log data is input.

The evaluation unit 254 evaluates the accuracy in estimating the degradation levels of the battery 11 in each of the first degradation level estimation model and the second degradation level estimation model generated by the generation unit 253.

Specifically, the evaluation unit 254 acquires the log data (hereinafter, second log data) indicating the state of the battery 11 during second charge with reference to the log data stored in the memory 22. The second charge is charge for charging the battery 11 until the SOC of the battery 11 changes from 0% to 100% in a case where the temperature of the battery 11 is between 20 degrees and 30 degrees.

The evaluation unit 254 calculates second degradation levels, which are the degradation levels of the battery 11 during the second charge, with the point-to-point OCV estimation method using the second log data in the same manner as the acquisition unit 251.

For each of the first degradation level estimation model and the second degradation level estimation model, the evaluation unit 254 calculates a deviation level between the degradation levels of the battery 11 output (estimated) by inputting the second log data to each degradation level estimation model and the second degradation levels. The deviation level is, for example, a root mean square error (RMSE) or a mean square error (MSE). However, the deviation level is not limited thereto.

Then, the evaluation unit 254 evaluates a degradation level estimation model having the deviation level being minimum in the first degradation level estimation model and the second degradation level estimation model, as a degradation level estimation model having the best accuracy in estimating the degradation levels of the battery 11 (hereinafter, the best evaluation model). The evaluation unit 254 stores the best evaluation model in the memory 22.

The output unit 255 transmits (outputs) the best evaluation model stored in the memory 22 to the battery-equipped device 1 using the communication unit 23.

In a case where the communication unit 23 receives a request for transmission of the degradation level estimation model from the battery-equipped device 1, the output unit 255 returns (outputs) the best evaluation model stored in the memory 22 to the battery-equipped device 1 using the communication unit 23.

### (Model Manufacturing Process)

Next, the model manufacturing process executed by the server 2 will be described. The model manufacturing process is a process for generating a plurality of degradation level estimation models for estimating the degradation levels of the battery 11, based on the log data acquired from the battery-equipped device 1, and outputting a degradation level estimation model having the best accuracy in estimating the degradation levels among the plurality of degradation level estimation models.

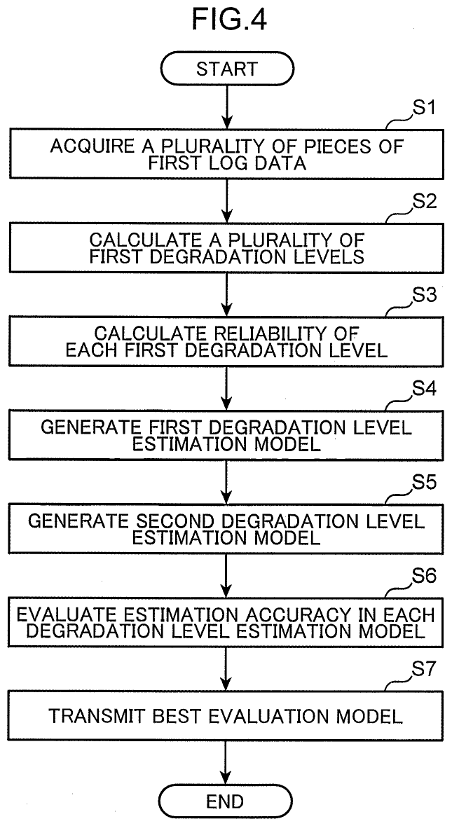

FIG. 4 is a flowchart illustrating one example of the model manufacturing process. For example, the control unit 25 periodically executes the model manufacturing process in a predetermined cycle such as once a day. The timing when the control unit 25 executes the model manufacturing process is not limited thereto. For example, the control unit 25 may execute the model manufacturing process every time the communication unit 23 receives, from the battery-equipped device 1, log data indicating that the battery 11 is in the suspended state immediately after charge-discharge, that is, every time the charge-discharge is performed in the battery-equipped device 1.

First, in step S1, the acquisition unit 251 acquires, from the memory 22, the plurality of pieces of first log data indicating the state of the battery 11 during charge or discharge.

Next, in step S2, the acquisition unit 251 calculates a first degradation level, which is the degradation level of the battery 11 during the first charge-discharge corresponding to each piece of the first log data acquired in step S1, with the degradation level estimation method. As a result, the acquisition unit 251 calculates the plurality of first degradation levels.

Next, in step S3, the calculation unit 252 calculates the reliability of the first degradation level corresponding to each piece of the first log data based on the content of the first charge-discharge corresponding to each piece of the first log data acquired in step S1.

Next, in step S4, the generation unit 253 generates the first degradation level estimation model by machine-learning the relationship between the plurality of first degradation levels calculated in step S2 and the plurality of pieces of first log data acquired in step S1.

Next, in step S5, the generation unit 253 generates the second degradation level estimation model by machine-learning the relationship between the first degradation levels having the reliability calculated in step S3 greater than or equal to the predetermined value among the plurality of first degradation levels calculated in step S2 and the first log data corresponding to such first degradation levels.

Next, in step S6, the evaluation unit 254 evaluates the accuracy in estimating the degradation levels of the battery 11 in each of the first degradation level estimation model and the second degradation level estimation model generated respectively in steps S4 and S5. The evaluation unit 254 stores, in the memory 22, the best evaluation model evaluated to have the estimation accuracy being best in the first degradation level estimation model and the second degradation level estimation model.

Next, in step S7, the output unit 255 transmits the best evaluation model stored in the memory 22 to the battery-equipped device 1 using the communication unit 23.

As described above, in the configuration of the first embodiment, the plurality of pieces of first log data indicating the state of the battery during charge or discharge is acquired from the battery-equipped device 1. Therefore, this configuration makes it possible to acquire the plurality of pieces of first log data necessary for machine learning for generating the first degradation level estimation model and the second degradation level estimation model acquire more quickly than a case where the first log data is acquired by conducting a plurality of charge-discharge tests in a test environment. As a result, this configuration makes it possible to quickly generate the first degradation level estimation model and the second degradation level estimation model.

Further, in the configuration of the first embodiment, the second degradation level estimation model is generated by machine-learning the relationship between the first degradation levels having the reliability greater than or equal to a predetermined value and the first log data corresponding to such first degradation levels. Therefore, this configuration makes it possible to generate the second degradation level estimation model that is considered to estimate the degradation levels of the battery 11 with higher accuracy than the first degradation level estimation model that is likely to have machine-learned the relationship between first degradation levels having reliability less than the predetermined value and the first log data used for calculating such first degradation levels.

However, even the second degradation level estimation model generated in this manner does not always have the accuracy in estimating the degradation levels of the battery 11 higher than that of the first degradation level estimation model. Therefore, in the configuration of the first embodiment, the accuracy in estimating the degradation levels of the battery 11 in each of the first degradation level estimation model and the second degradation level estimation model is evaluated, and the best evaluation model evaluated to have the best estimation accuracy is transmitted to the battery-equipped device 1. Thus, with this configuration, the degradation level estimation model that can accurately estimate the degradation levels of the battery 11 can be transmitted to the battery-equipped device 1.

### Second Embodiment

Next, a second embodiment of the present disclosure will be described. The first embodiment has described the example in which the first degradation level estimation model and the second degradation level estimation model are generated in the server 2, and the best evaluation model evaluated to have the best accuracy in estimating the degradation levels in the first degradation level estimation model and the second degradation level estimation model is output.

In the second embodiment, in the server 2, a third degradation level estimation model (third learned model) different from the first degradation level estimation model and the second degradation level estimation model is further generated by using the first log data. Then, the accuracy in estimating the degradation levels by each of the first degradation level estimation model, the second degradation level estimation model, and the third degradation level estimation model is evaluated, and the best evaluation model evaluated to have the best accuracy in estimating the degradation levels is output. Note that in the following description, the same components as those of the first embodiment are denoted by the same reference signs as those of the first embodiment, and will be omitted from the description.

In the second embodiment, the calculation unit 252 further extracts first degradation levels that fall within a predetermined variation range from the plurality of first degradation levels calculated in step S2 (FIG. 4).

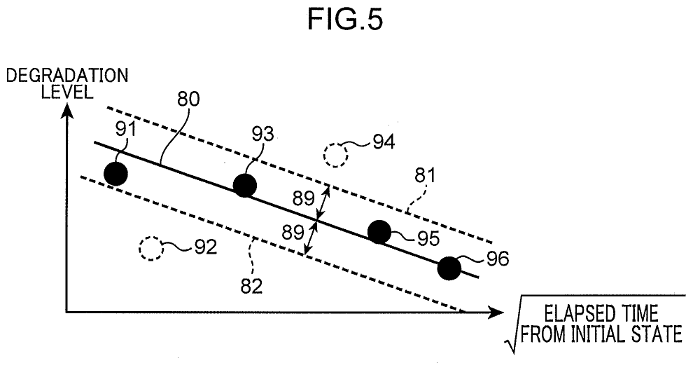

FIG. 5 is a diagram illustrating one example of a process for extracting the first degradation levels within the predetermined variation range. The horizontal axis in FIG. 5 represents the square root of the elapsed time from the time point at which the battery 11 is in the initial state to the time point at which the first charge-discharge corresponding to each of the first degradation levels calculated in step S2 (FIG. 4) ends. The first charge-discharge corresponding to the first degradation levels indicates the first charge-discharge corresponding to the first log data used for calculating the first degradation levels. In FIG. 5, the vertical axis represents the degradation levels of the battery 11. Reference numerals 91 to 96 denote examples of the plurality of first degradation levels calculated in step S2 (FIG. 4).

Specifically, as illustrated in FIG. 5, the calculation unit 252 performs linear regression in which the square root of the elapsed time from the time point at which the battery 11 is in the initial state to the time point at which the first charge-discharge corresponding to each of the plurality of first degradation levels 91 to 96 calculated in step S2 (FIG. 4) ends is used as an explanatory variable and the plurality of first degradation levels 91 to 96 is used as objective variables.

The calculation unit 252 extracts, as first degradation levels within a predetermined variation range, the first degradation levels 91, 93, 95, and 96 at which a distance to a regression line 80 obtained by the linear regression is a predetermined distance 89 or shorter among the plurality of first degradation levels 91 to 96 calculated in step S2 (FIG. 4).

Similarly to the first degradation level estimation model and the second degradation level estimation model, the generation unit 253 further generates the third degradation level estimation model by machine-learning the relationship between the first degradation levels within a predetermined variation range extracted by the calculation unit 252 and the first log data corresponding to such first degradation levels.

In step S6 (FIG. 4), the evaluation unit 254 further evaluates the accuracy in estimating the degradation levels of the battery 11 in the third degradation level estimation model, similarly to the first degradation level estimation model and the second degradation level estimation model. The evaluation unit 254 stores, in the memory 22, the best evaluation model evaluated to having the best accuracy in estimating the degradation levels of the battery 11 among the first degradation level estimation model, the second degradation level estimation model, and the third degradation level estimation model.

In step S7 (FIG. 4), the output unit 255 transmits the best evaluation model stored in the memory 22 to the battery-equipped device 1 using the communication unit 23.

In the configuration of the second embodiment, the third degradation level estimation model is generated by machine-learning the relationship between the first degradation levels within the predetermined variation range and the first log data corresponding to such first degradation levels. Therefore, this configuration makes it possible to generate the third degradation level estimation model that is considered to estimate the degradation levels of the battery 11 with higher accuracy than the first degradation level estimation model that is likely to have machine-learned the relationship between the first degradation levels outside the variation range and the first log data corresponding to the first degradation levels.

However, even the third degradation level estimation model generated in this manner does not always have the accuracy in estimating the degradation levels of the battery higher than that of the first degradation level estimation model and the second degradation level estimation model. Therefore, in the configuration of the second embodiment, the accuracy in estimating the degradation levels of the battery 11 by the third degradation level estimation model is further evaluated, and the best evaluation model evaluated to have the best estimation accuracy among the first degradation level estimation model, the second degradation level estimation model, and the third degradation level estimation model is transmitted to the battery-equipped device 1. Thus, with this configuration, the degradation level estimation model that can accurately estimate the degradation levels of the battery 11 can be transmitted to the battery-equipped device 1.

### Third Embodiment

Next, a third embodiment of the present disclosure will be described. The second embodiment has described the example in which the first degradation level estimation model, the second degradation level estimation model, and the third degradation level estimation model are generated in the server 2, and the best evaluation model evaluated to have the best accuracy in estimating the degradation levels among the first degradation level estimation model, the second degradation level estimation model, and the third degradation level estimation model is output.

In the third embodiment, in the server 2, a fourth degradation level estimation model (fourth learned model) different from the first degradation level estimation model, the second degradation level estimation model, and the third degradation level estimation model is further generated by using the first log data. Then, the accuracy in estimating the degradation levels estimated by each of the first degradation level estimation model, the second degradation level estimation model, the third degradation level estimation model, and the fourth degradation level estimation model is evaluated, and the best evaluation model evaluated to have the best estimation accuracy of the degradation levels is output. Note that in the following description, the same components as those of the second embodiment are denoted by the same reference signs as those of the second embodiment, and will be omitted from the description.

In the third embodiment, similarly to the first degradation level estimation model and the second degradation level estimation model, the generation unit 253 further generates the fourth degradation level estimation model that has machine-learned the relationship between the first degradation levels having the reliability calculated in step S3 (FIG. 4) being greater than or equal to a predetermined value among the first degradation levels within the predetermined variation range extracted by the calculation unit 252 and the first log data corresponding to such first degradation levels.

In step S6 (FIG. 4), the evaluation unit 254 further evaluates the accuracy in estimating the degradation levels of the battery 11 in the fourth degradation level estimation model, similarly to the first degradation level estimation model and the second degradation level estimation model. The evaluation unit 254 stores, in the memory 22, the best evaluation model evaluated to having the best accuracy in estimating the degradation levels of the battery 11 among the first degradation level estimation model, the second degradation level estimation model, the third degradation level estimation model, and the fourth degradation level estimation model.

In step S7 (FIG. 4), the output unit 255 transmits the best evaluation model stored in the memory 22 to the battery-equipped device 1 using the communication unit 23.

In the configuration of the third embodiment, the fourth degradation level estimation model is generated by machine-learning the relationship between the first degradation levels having the reliability greater than or equal to the predetermined value among the first degradation levels within the predetermined variation range and the first log data corresponding to such first degradation levels. Therefore, this configuration makes it possible to generate the fourth degradation level estimation model that is considered to estimate the degradation levels of the battery 11 with higher accuracy than the third degradation level estimation model that is likely to have machine-learned the relationship between the first degradation levels having reliability less than the predetermined value among the first degradation levels within the variation range and the first log data used for calculating such first degradation levels.

However, even the fourth degradation level estimation model generated in this manner does not always have the accuracy in estimating the degradation levels of the battery 11 higher than that of the first degradation level estimation model, the second degradation level estimation model, and the third degradation level estimation model. Therefore, in the configuration of the third embodiment, the accuracy in estimating the degradation levels of the battery 11 estimated by the fourth degradation level estimation model is further evaluated, and the degradation level estimation model evaluated to have the best estimation accuracy among the first degradation level estimation model, the second degradation level estimation model, the third degradation level estimation model, and the fourth degradation level estimation model is transmitted to the battery-equipped device 1. Thus, with this configuration, the degradation level estimation model that can accurately estimate the degradation levels of the battery 11 can be transmitted.

The first embodiment, the second embodiment, and the third embodiment have described the examples of the configurations in which the acquisition unit 251 acquires the plurality of pieces of first log data from the memory 22 in step S1 (FIG. 4), and calculates the plurality of first degradation levels with the degradation level estimation method using the plurality of pieces of first log data in step S2 (FIG. 4).

Alternatively, the acquisition unit 251 may acquire the plurality of first log data from an external device different from the server 2 using the communication unit 23, and may acquire the plurality of first degradation levels calculated with the degradation level estimation method using the plurality of pieces of first log data.

Similarly, in step S6 (FIG. 4), the evaluation unit 254 may acquire the second log data indicating the state of the battery 11 during the second charge from an external device different from the server 2 using the communication unit 23 and the second degradation levels calculated with the degradation level estimation method using the second log data.

The technique according to the present disclosure enables quickly output of a learned model capable of accurately estimating the degradation levels of a chargeable-dischargeable battery to a device, such as an electric vehicle, equipped with the battery. Thus, this technique is useful in displaying the degradation levels of the battery with high accuracy in the device.

1. A manufacturing method in a manufacturing device of a learned model that estimates a degradation level of a battery being chargeable and dischargeable, the manufacturing method comprising:
acquiring a plurality of pieces of first log data acquired from a device equipped with the battery and a plurality of first degradation levels calculated with a degradation level estimation method using each of the plurality of pieces of first log data, the plurality of pieces of first log data indicating a state of the battery during charge or discharge, the plurality of first degradation levels indicating degradation levels of the battery;
calculating reliability indicating probability of each of the plurality of first degradation levels respectively corresponding to the plurality of pieces of first log data, based on a content of first charge-discharge that is charge or discharge respectively corresponding to the plurality of pieces of first log data;
generating a first learned model by machine-learning a relationship between the plurality of first degradation levels and the plurality of pieces of first log data;
generating a second learned model by machine-learning a relationship between first degradation levels having the reliability greater than or equal to a predetermined value among the plurality of first degradation levels and first log data corresponding to the first degradation levels having the reliability greater than or equal to the predetermined value among the plurality of pieces of first log data;
evaluating accuracy in estimating the degradation levels of the battery in each of the first learned model and the second learned model; and
outputting a learned model evaluated to have the estimation accuracy being best in the first learned model and the second learned model.

2. The manufacturing method according to claim 1, further comprising:
extracting first degradation levels within a predetermined variation range among the plurality of first degradation levels; and
generating a third learned model by machine-learning a relationship between the extracted first degradation levels and first log data corresponding to the extracted first degradation levels,
wherein the evaluating includes further evaluating the estimation accuracy in the third learned model, and
wherein the outputting includes outputting a learned model evaluated to have the estimation accuracy being best among the first learned model, the second learned model, and the third learned model.

3. The manufacturing method according to claim 2, further comprising:
generating a fourth learned model by machine-learning a relationship between first degradation levels having the reliability greater than or equal to the predetermined value among the extracted first degradation levels and first log data corresponding to the first degradation levels having the reliability greater than or equal to the predetermined value among the extracted first degradation levels,
wherein the evaluating further includes evaluating the estimation accuracy in the fourth learned model, and
wherein the outputting includes outputting a learned model evaluated to have the estimation accuracy being best among the first learned model, the second learned model, the third learned model, and the fourth learned model.

4. The manufacturing method according to claim 1, wherein the evaluating includes
acquiring second log data acquired from the device equipped with the battery and second degradation levels calculated with the degradation level estimation method using the second log data, the second log data indicating a state of the battery during second charge for charging the battery until an SOC of the battery changes from 0% to 100% in a case where a temperature of the battery is between 20 degrees and 30 degrees, the second degradation levels indicating degradation levels of the battery,
calculating a deviation level between the second degradation levels and degradation levels of the battery estimated by inputting the second log data to each of the plurality of learned models to be evaluated; and
evaluating a learned model having the deviation level being lowest among the plurality of learned models as the learned model having the best estimation accuracy.

5. The manufacturing method according to claim 1, wherein
the calculating the reliability includes calculating, as the reliability, a result of multiplying an initial value of the reliability greater than the predetermined value by a coefficient corresponding to the content of the first charge-discharge.

6. The manufacturing method according to claim 5, wherein
the coefficient is determined as a difference between an SOC of the battery at start of the first charge-discharge and an SOC of the battery at end of the first charge-discharge.

7. The manufacturing method according to claim 5, wherein
the calculating the reliability includes performing multiplication by a coefficient smaller than 1 in a case where a time during which the battery is in a suspended state immediately before the first charge-discharge is shorter than a predetermined time.

8. The manufacturing method according to claim 5, wherein
the calculating the reliability includes performing multiplication by a coefficient smaller than 1 in a case where each of the plurality of first degradation levels respectively corresponding to the plurality of pieces of first log data is greater than a predetermined upper limit value or smaller than a predetermined lower limit value.

9. The manufacturing method according to claim 7, wherein
the calculating the reliability includes performing multiplication by a coefficient smaller than 1 in a case where each of the plurality of first degradation levels respectively corresponding to the plurality of pieces of first log data is greater than a predetermined upper limit value or smaller than a predetermined lower limit value.

10. The manufacturing method according to claim 1, wherein
the degradation level estimation method includes
acquiring a voltage of the battery in a battery suspended state each of immediately before and after the first charge-discharge as an open circuit voltage of the battery each of immediately before and after the first charge-discharge,
designating the open circuit voltage of the battery each of immediately before and after the first charge-discharge as an SOC of the battery at each of start and end of the first charge-discharge, with reference to information indicating a relationship between the SOC of the battery and the open circuit voltage of the battery,
calculating a difference in the SOC of the battery at each of the start and the end of the first charge-discharge,
calculating an integrated value of currents of the battery during the first charge-discharge using each of the plurality of pieces of first log data, and
calculating, as the degradation level of the battery, a result of dividing a result of dividing the integrated value by the difference by a full charge capacity of the battery in an initial state.

11. The manufacturing method according to claim 4, wherein
the degradation level estimation method includes
acquiring a voltage of the battery in a battery suspended state each of immediately before and after the second charge as an open circuit voltage of the battery each of immediately before and after the second charge,
designating the open circuit voltage of the battery each of immediately before and after the second charge as the SOC of the battery at each of the start and the end of the second charge, with reference to information indicating a relationship between the SOC of the battery and the open circuit voltage of the battery,
calculating a difference in the SOC of the battery at each of the start and the end of the second charge,
calculating an integrated value of currents of the battery during the second charge using the second log data, and
calculating a result of dividing a result of dividing the integrated value by the difference by a full charge capacity of the battery in an initial state, as the degradation level of the battery.

12. The manufacturing method according to claim 2, wherein
the extracting the first degradation levels within the variation range includes
performing linear regression in which a square root of an elapsed time from an initial state of the battery to end of the first charge-discharge is an explanatory variable and each of the first degradation levels is an objective variable, and
extracting first degradation levels at which a distance up to a regression line obtained by the linear regression is a predetermined distance or shorter among the plurality of first degradation levels, as the first degradation levels within the variation range.

13. A manufacturing device of a learned model that estimates a degradation level of a battery being chargeable and dischargeable, the manufacturing device comprising:
an acquisition unit that acquires a plurality of pieces of first log data acquired from a device equipped with the battery and a plurality of first degradation levels calculated with a degradation level estimation method using each of the plurality of pieces of first log data, the plurality of pieces of first log data indicating a state of the battery during charge or discharge, the plurality of first degradation levels indicating degradation levels of the battery;
a calculation unit that calculates reliability indicating probability of each of the plurality of first degradation levels respectively corresponding to the plurality of pieces of first log data, based on a content of first charge-discharge that is charge or discharge respectively corresponding to each of the plurality of pieces of first log data;
a first generation unit that generates a first learned model by machine-learning a relationship between the plurality of first degradation levels and the plurality of pieces of first log data;
a second generation unit that generates a second learned model by machine-learning a relationship between first degradation levels having the reliability greater than or equal to a predetermined value among the plurality of first degradation levels and first log data corresponding to the first degradation levels having the reliability greater than or equal to the predetermined value among the plurality of pieces of first log data;
an evaluation unit that evaluates accuracy in estimating the degradation levels of the battery in each of the first learned model and the second learned model; and
an output unit that outputs a learned model evaluated to have the estimation accuracy being best in the first learned model and the second learned model.

14. A non-transitory computer readable storage medium storing a program of a manufacturing device of a learned model that estimates a degradation level of a battery being chargeable and dischargeable, the program causing the manufacturing device to perform operations comprising:
acquiring a plurality of pieces of first log data acquired from a device equipped with the battery and a plurality of first degradation levels calculated with a degradation level estimation method using each of the plurality of pieces of first log data, the plurality of pieces of first log data indicating a state of the battery during charge or discharge, the plurality of first degradation levels indicating degradation levels of the battery;
calculating reliability indicating probability of each of the plurality of first degradation levels respectively corresponding to the plurality of pieces of first log data, based on a content of first charge-discharge that is charge or discharge respectively corresponding to the plurality of pieces of first log data;
generating a first learned model by machine-learning a relationship between the plurality of first degradation levels and the plurality of pieces of first log data;
generating a second learned model by machine-learning a relationship between first degradation levels having the reliability greater than or equal to a predetermined value among the plurality of first degradation levels and first log data corresponding to the first degradation levels having the reliability greater than or equal to the predetermined value among the plurality of pieces of first log data;
evaluating accuracy in estimating the plurality of degradation levels of the battery in each of the first learned model and the second learned model; and
outputting a learned model evaluated to have the estimation accuracy being best in the first learned model and the second learned model.
